(19) United States
(12) Patent Application Publication
(10) Pub. No.: US 2025/0253823 A1
(43) Pub. Date: Aug. 7, 2025

(54) TERMINATION CIRCUIT WITH AMPLITUDE AND PHASE IMBALANCE-TUNING TECHNIQUE

(71) Applicant: MediaTek Inc., Hsinchu City (TW)

(72) Inventors: Min-Jui Chiu, Hsinchu City (TW); Hung-Yi Huang, Hsinchu City (TW); Wei-Te Lin, Hsinchu City (TW)

(73) Assignee: MediaTek Inc., Hsinchu City (TW)

(21) Appl. No.: 19/026,155

(22) Filed: Jan. 16, 2025

Related U.S. Application Data
(60) Provisional application No. 63/627,811, filed on Feb. 1, 2024.

(51) Int. Cl. H03H 7/42

(52) U.S. Cl. CPC H03H 7/42

(57) ABSTRACT

An on-chip variable termination circuit includes a plurality of first tuning circuits and a plurality of second tuning circuits. Each of the first tuning circuits is coupled between a positive signal node of a differential signal port and a voltage node. The first tuning circuits include at least one amplitude tuning circuit and at least one phase tuning circuit. Each of the second tuning circuits is coupled between a negative signal node of the differential signal port and the voltage node. The second tuning circuits include at least one amplitude tuning circuit and at least one phase tuning circuit.

### CROSS REFERENCE TO RELATED APPLICATIONS

This application claims the benefit of U.S. Provisional Application No. 63/627,811, filed on Feb. 1, 2024. The content of the application is incorporated herein by reference.

### BACKGROUND

The present invention relates to a termination circuit design, and more particularly, to a termination circuit with an amplitude and phase imbalance-tuning technique (APIT) for even-order distortion reduction.

A digital-to-analog converter (DAC) may generate and output differential signals (i.e., differential DAC outputs) to a following processing stage through an output network. For example, the output network may include a balanced to unbalanced (balun) for transforming the differential signals into a single-ended signal. The balun may have small insertion loss, but may introduce large amplitude/phase imbalance between a positive signal and a negative signal of the differential signals, which results in serious even-order distortion and degrades the DAC performance. Similarly, an analog-to-digital converter (ADC) may receive differential signals (i.e., differential ADC inputs) from a preceding processing stage through an input network. For example, the input network may include a balun for transforming a single-ended signal into the differential signals. The balun may have small insertion loss, but may introduce large amplitude/phase imbalance between a positive signal and a negative signal of the differential signals, which results in serious even-order distortion and degrades the ADC performance.

Thus, there is a need for an innovative amplitude/phase imbalance compensation design for a DAC output network and/or an ADC input network.

### SUMMARY

One of the objectives of the claimed invention is to provide a termination circuit with APIT for even-order distortion reduction.

According to a first aspect of the present invention, an exemplary termination circuit is disclosed. The exemplary termination circuit includes an on-chip variable termination circuit. The on-chip variable termination circuit includes a plurality of first tuning circuits and a plurality of second tuning circuits. Each of the first tuning circuits is coupled between a positive signal node of a differential signal port and a voltage node. The first tuning circuits include at least one amplitude tuning circuit and at least one phase tuning circuit. Each of the second tuning circuits is coupled between a negative signal node of the differential signal port and the voltage node. The second tuning circuits include at least one amplitude tuning circuit and at least one phase tuning circuit.

According to a second aspect of the present invention, an exemplary termination circuit is disclosed. The exemplary termination circuit includes an on-chip variable termination circuit. The on-chip variable termination circuit includes a plurality of first tuning circuits and a plurality of second tuning circuits. Each of the first tuning circuits is coupled between a positive signal node of a differential signal port and a voltage node. Each of the second tuning circuits is coupled between a negative signal node of the differential signal port and the voltage node. Each of the first tuning circuits and the second tuning circuits is a reconfigurable tuning circuit that is configured or reconfigured to act as either an amplitude tuning circuit or a phase tuning circuit.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a first processing circuit using a proposed termination circuit according to an embodiment of the present invention.

FIG. 2 is a diagram illustrating a second processing circuit using a proposed termination circuit according to an embodiment of the present invention.

FIG. 3 is a diagram illustrating a first on-chip variable termination circuit according to an embodiment of the present invention.

FIG. 4 is a diagram illustrating an amplitude tuning circuit according to an embodiment of the present invention.

FIG. 5 is a diagram illustrating a phase tuning circuit according to an embodiment of the present invention.

FIG. 6 is a diagram illustrating a second on-chip variable termination circuit according to an embodiment of the present invention.

FIG. 7 is a diagram illustrating a reconfigurable tuning circuit according to an embodiment of the present invention.

FIG. 8 is a diagram illustrating the reconfigurable tuning circuit shown in FIG. 7 that is configured (or reconfigured) as an amplitude tuning circuit.

FIG. 9 is a diagram illustrating the reconfigurable tuning circuit shown in FIG. 7 that is configured (or reconfigured) as a phase tuning circuit.

FIG. 10 is a diagram illustrating a third on-chip variable termination circuit according to an embodiment of the present invention.

FIG. 11 is a diagram illustrating a fourth on-chip variable termination circuit according to an embodiment of the present invention.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

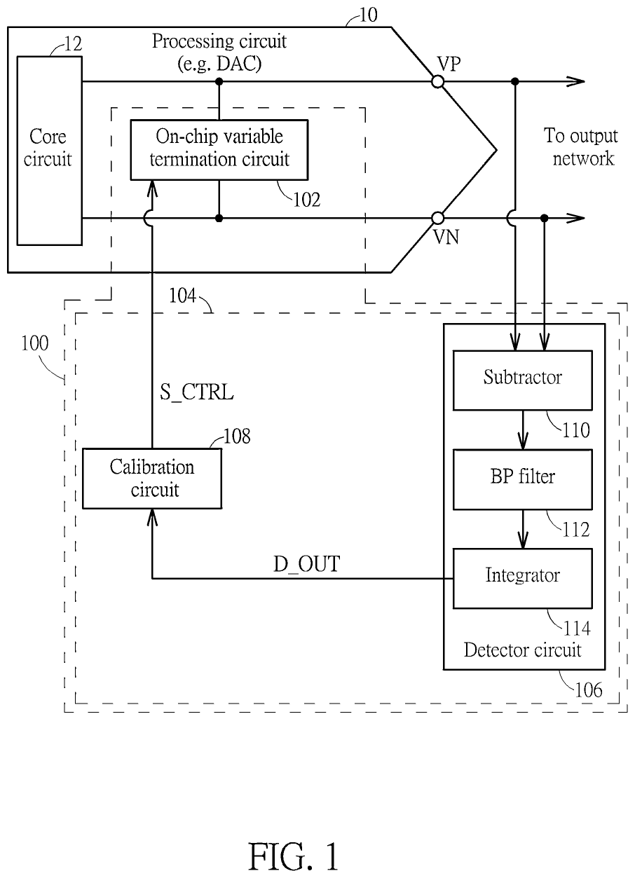

FIG. 1 is a diagram illustrating a first processing circuit using a proposed termination circuit according to an embodiment of the present invention. By way of example, but not limitation, the processing circuit 10 may be a DAC, and the core circuit 12 may support a DAC function. The processing circuit 10 has a differential signal output port consisting of a positive signal node VP and a negative signal node VN. A termination circuit 100 with auto-calibration includes an on-chip variable termination circuit (particularly, on-chip variable termination circuit with APIT) 102 and an auto-calibration circuit 104. In this embodiment, the auto-calibration circuit 104 includes a detector circuit 106 and a calibration circuit 108, where the detector circuit 106 includes a subtractor 110, a band-pass (BP) filter 112, and an integrator 114. For example, the subtractor 110 may be implemented by a balun or an amplifier. In some embodiments of the present invention, the differential signal output port may be coupled to an output network, and the output network may include a balun. However, this is not meant to be a limitation of the present invention. In practice, the proposed on-chip variable termination circuit (particularly, on-chip variable termination circuit with APIT) 102 is not limited to an application using a balun. Any processing circuit using the proposed on-chip variable termination circuit (particularly, on-chip variable termination circuit with APIT) 102 coupled between the positive signal node VP and the negative signal node VN of the differential signal output port falls within the scope of the present invention.

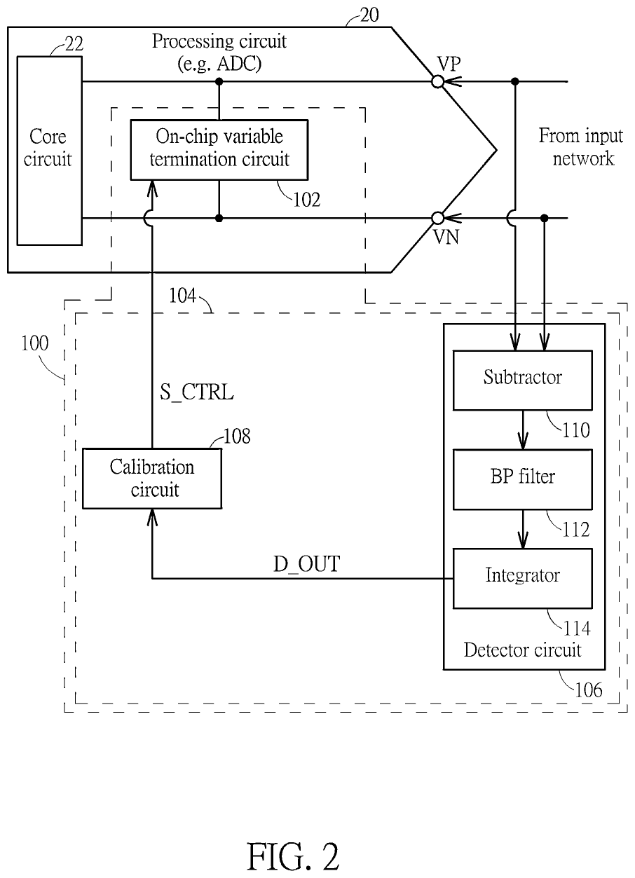

FIG. 2 is a diagram illustrating a second processing circuit using a proposed termination circuit according to an embodiment of the present invention. By way of example, but not limitation, the processing circuit 20 may be an ADC, and the core circuit 22 may support an ADC function. The processing circuit 20 has a differential signal input port consisting of a positive signal node VP and a negative signal node VN. The same termination circuit 100 shown in FIG. 1 may be employed by the processing circuit 20. In some embodiments of the present invention, the differential signal input port may be coupled to an input network, and the input network may include a balun. However, this is not meant to be a limitation of the present invention. In practice, the proposed on-chip variable termination circuit (particularly, on-chip variable termination circuit with APIT) 102 is not limited to an application using a balun. Any processing circuit using the proposed on-chip variable termination circuit (particularly, on-chip variable termination circuit with APIT) 102 coupled between the positive signal node VP and the negative signal node VN of the differential signal input port falls within the scope of the present invention.

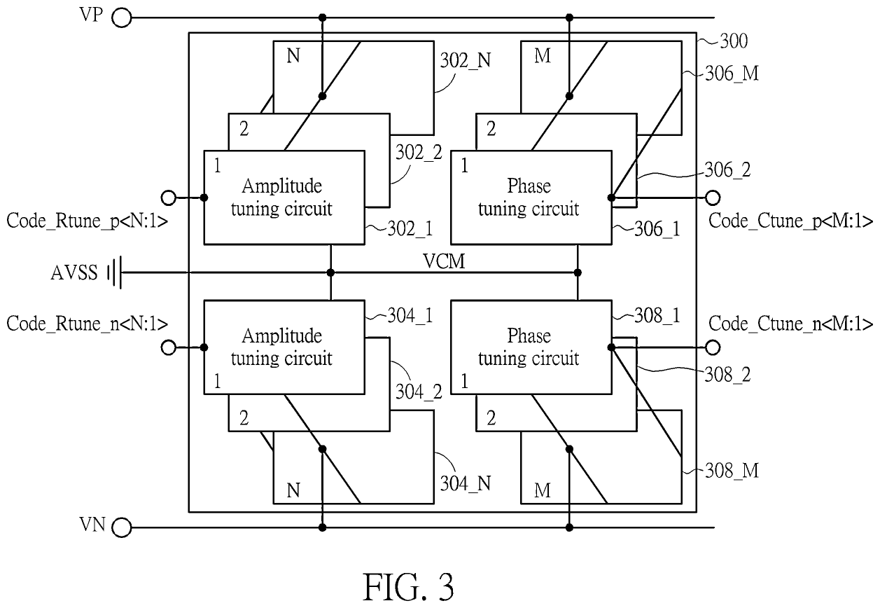

FIG. 3 is a diagram illustrating a first on-chip variable termination circuit according to an embodiment of the present invention. The on-chip variable termination circuit 102 shown in any of FIG. 1 and FIG. 2 may be implemented using the on-chip variable termination circuit 300. The on-chip variable termination circuit 300 includes N (N≥1) amplitude tuning circuits 302_1-302_N coupled between the positive signal node VP and a voltage node VCM, N (N≥1) amplitude tuning circuits 304_1-304_N coupled between the negative signal node VN and the voltage node VCM, M (M≥1) phase tuning circuits 306_1-306_M coupled between the positive signal node VP and the voltage node VCM, and M (M≥1) phase tuning circuits 308_1-308_M coupled between the negative signal node VN and the voltage node VCM. In this embodiment, the voltage node VCM is configured to receive a common-mode voltage set by a fixed reference voltage AVSS (AVSS=0V). The amplitude tuning circuits 302_1-302_N are enabled/disabled by N amplitude-tuning control signals Code_Rtune_p<N:1>, respectively. The amplitude tuning circuits 304_1-304_N are enabled/disabled by N amplitude-tuning control signals Code_Rtune_n<N:1>, respectively. The phase tuning circuits 306_1-306_M are enabled/disabled by M phase-tuning control signals Code_Ctune_p<M:1>, respectively. The phase tuning circuits 308_1-308_M are enabled/disabled by M phase-tuning control signals Code_Ctune_n<M:1>, respectively. It should be noted that values of N and M may be adjusted, depending upon actual design considerations.

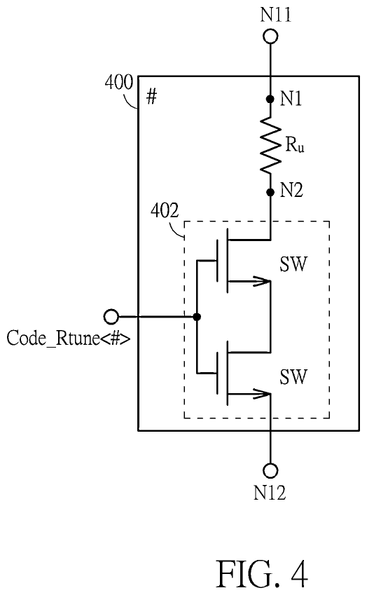

In this embodiment, each amplitude tuning circuit employed by the on-chip variable termination circuit 300 is a non-reconfigurable amplitude tuning circuit. FIG. 4 is a diagram illustrating an amplitude tuning circuit according to an embodiment of the present invention. The amplitude tuning circuit 400 may be any of the amplitude tuning circuits 302_1-302_N and 304_1-304_N shown in FIG. 3. As shown in FIG. 4, the amplitude tuning circuit 400 includes a unit resistor Rᵤ and a switch 402 implemented using two metal-oxide-semiconductor (MOS) transistors (labeled by “SW”). The unit resistor Rᵤ has a first end N1 and a second end N2, where the first end N1 is coupled to a first node N11 of the amplitude tuning circuit 400. The switch 402 is controlled by an amplitude-tuning control signal Code_Rtune<#>, and is coupled between the second end N2 of the unit resistor Rᵤ and a second node N12 of the amplitude tuning circuit 400. When the amplitude-tuning control signal Code_Rtune<#> has a logic-high level “1”, the switch 402 is turned on to enable the unit resistor Rᵤ to make contribution to the amplitude imbalance compensation. When signal the amplitude-tuning control Code_Rtune<#> has a logic-low level “0”, the switch 402 is turned off to block the unit resistor Rᵤ from making contribution to the amplitude imbalance compensation.

One of the first node N11 and the second node N12 of the amplitude tuning circuit 400 is coupled to one of the positive signal node VP and the negative signal node VN of the differential signal port (which may be a differential signal output port of a DAC or a differential signal input port of an ADC). The other of the first node N11 and the second node N12 of the amplitude tuning circuit 400 is coupled to the voltage node VCM (which may be coupled to a fixed reference voltage AVSS). From the perspective of performance, the first node N11 is preferably coupled to one of the positive signal node VP and the negative signal node VN, and the second node N12 is preferably coupled to the voltage node VCM. However, this is not meant to be a limitation of the present invention.

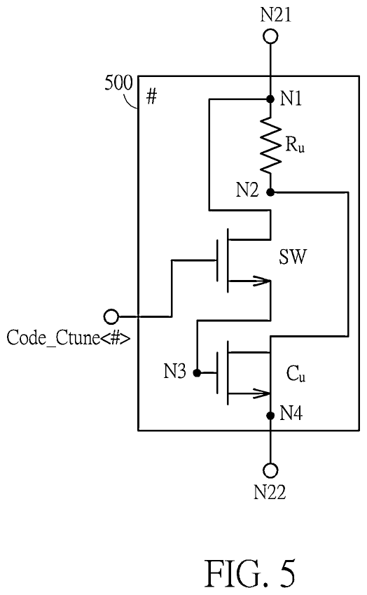

In this embodiment, each phase tuning circuit employed by the on-chip variable termination circuit 300 is a non-reconfigurable phase tuning circuit. FIG. 5 is a diagram illustrating a phase tuning circuit according to an embodiment of the present invention. The phase tuning circuit 500 may be any of the phase tuning circuits 306_1-306_M and 308_1-308_M shown in FIG. 3. To ensure layout consistency, the amplitude tuning circuit 400 and the phase tuning circuit 500 may have the same circuit components (e.g., one resistor and two MOS transistors) but different circuit connections. However, this is for illustrative purposes only, and is not meant to be a limitation of the present invention. As shown in FIG. 5, the phase tuning circuit 500 includes a unit resistor Rᵤ, a switch SW implemented using one MOS transistor, and a unit capacitor Cᵤ implemented using another MOS transistor. The unit capacitor Cᵤ is a MOS capacitor, where a control terminal (e.g., gate terminal) of the MOS transistor acts as a first end N3 of the unit capacitor Cᵤ, and a first connection terminal (e.g., drain terminal) and a second connection terminal (e.g., source terminal) of the MOS transistor are connected to each other to act as a second end N4 of the unit capacitor Cᵤ. The second end N4 of the unit capacitor Cᵤ is coupled to a second node N22 of the phase tuning circuit 500. The switch SW is a MOS switch controlled by a phase-tuning control signal Code_Ctune<#>, and is coupled between a first node N21 of the phase tuning circuit 500 and the first end N3 of the unit capacitor Cᵤ. When the phase-tuning control signal Code_Ctune<#> has a logic-high level “1”, the switch SW is turned on to enable the unit capacitor Cᵤ to make contribution to the phase imbalance compensation. When the phase-tuning control signal Code_Ctune<#> has a logic-low level “0”, the switch SW is turned off to block the unit capacitor Cᵤ from making contribution to the phase imbalance compensation.

It should be noted that the unit resistor Rᵤ is constantly coupled between the first node N21 and the second node N22 of the phase tuning circuit 500 due to the MOS capacitor with the first connection terminal (e.g., drain terminal) and the second connection terminal (e.g., source terminal) connected to each other. Hence, the unit resistor Rᵤ of the phase tuning circuit 500 always makes contribution to the amplitude imbalance compensation regardless of the phase-tuning control signal Code_Ctune<#>. Even though all of the amplitude tuning circuits 302_1-302_N of the on-chip variable termination circuit 300 are disabled by the amplitude-tuning control signals Code_Rtune_p<N:1>, the phase tuning circuits 306_1-306_M are still capable of providing a resistive load Rᵤ/M for a positive signal of the differential signals. Similarly, even though all of the amplitude tuning circuits 304_1-304_N of the on-chip variable termination circuit 300 are disabled by the amplitude-tuning control signals Code_Rtune_n<N:1>, the phase tuning circuits 308_1-308_M are still capable of providing a resistive load Rᵤ/M for a negative signal of the differential signals.

The first node N21 of the phase tuning circuit 500 is coupled to one of the positive signal node VP and the negative signal node VN of the differential signal port (which may be a differential signal output port of a DAC or a differential signal input port of an ADC). And the second node N22 of the phase tuning circuit 500 is coupled to the voltage node VCM (which may be coupled to a fixed reference voltage AVSS).

With proper settings of the amplitude-tuning control signals Code_Rtune<N:1> (e.g., Code_Rtune_p<N:1> or Code_Rtune_n<N:1>) and the phase-tuning control signals Code_Ctune<M:1> (e.g., Code_Ctune_p<M:1> or Code_Ctune_n<M:1>), the capacitance term Cₜₑᵣₘ involved in phase imbalance compensation and the resistance term Rₜₑᵣₘ involved in amplitude imbalance compensation may be expressed using the following formulas.

$${C}_{term} = {\sum }_{i = 1}^{M} Code\_Ctune < i > \times {C}_{u} \qquad ( 1 )$$

$${R}_{term} = \frac{{R}_{u}}{M + {\sum }_{i = 1}^{N} Code\_Rtune < i >} \qquad ( 2 )$$

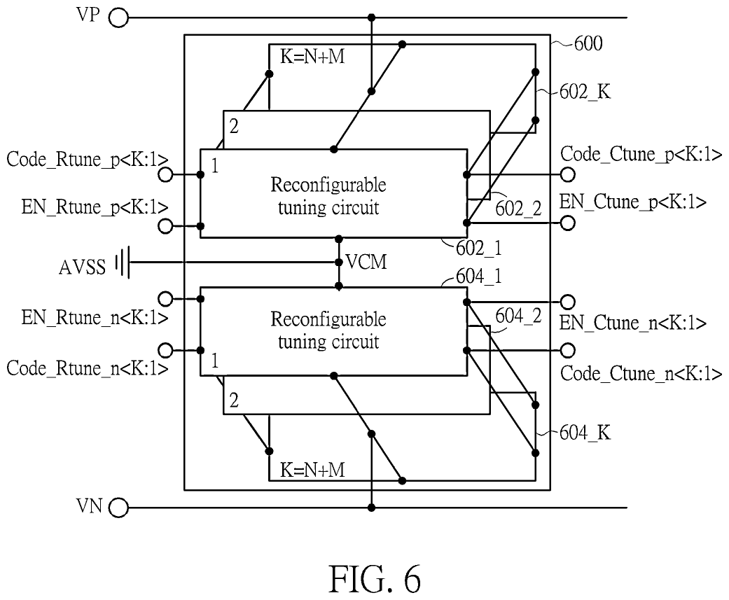

FIG. 6 is a diagram illustrating a second on-chip variable termination circuit according to an embodiment of the present invention. The on-chip variable termination circuit 102 shown in any of FIG. 1 and FIG. 2 may be implemented using the on-chip variable termination circuit 600. The on-chip variable termination circuit 600 includes K (e.g., K=N+M, where N≥1 and M≥1) reconfigurable tuning circuits 602_1-602_K coupled between the positive signal node VP and a voltage node VCM, and K (e.g., K=N+M, where N≥1 and M≥1) reconfigurable tuning circuits 604_1-604_K coupled between the negative signal node VN and the voltage node VCM. In this embodiment, the voltage node VCM is configured to receive a common-mode voltage set by a fixed reference voltage AVSS (AVSS=0V). The reconfigurable tuning circuits 602_1-602_K are controlled by K amplitude-tuning configuration enabling signals EN_Rtune_p<K:1>, K phase-tuning configuration enabling signals EN_Ctune_p<K:1>, K amplitude-tuning control signals Code_Rtune_p<K:1>, and K phase-tuning control signals Code_Ctune_p<K:1>. The reconfigurable tuning circuits 604_1-604_K are controlled by K amplitude-tuning configuration enabling signals EN_Rtune_n<K:1>, K phase-tuning configuration enabling signals EN_Ctune_n<K:1>, K amplitude-tuning control signals Code_Rtune_n<K:1>, and K phase-tuning control signals Code_Ctune_n<K:1>. It should be noted that the value of K may be adjusted, depending upon actual design considerations.

In this embodiment, each reconfigurable tuning circuit employed by the on-chip variable termination circuit 600 can be configured to act as one of an amplitude tuning circuit and a phase tuning circuit and can be reconfigured to act as the other of the amplitude tuning circuit and the phase tuning circuit. In other words, the same reconfigurable tuning circuit is capable of supporting both of an amplitude tuning circuit configuration and a phase tuning circuit configuration. Each of the reconfigurable tuning circuits 602_1-602_K and 604_1-604_K can be used as either an amplitude tuning circuit or a phase tuning circuit with the same cell for best process tracking ability. In addition, the reconfigurable tuning circuits 602_1-602_K (or 604_1-604_K) may be configured (or reconfigured) into a form of all amplitude tuning circuits (e.g., (N+M) amplitude tuning circuits), or a form of all phase tuning circuits (e.g., (N+M) phase tuning circuits), or a form of some amplitude tuning circuits (e.g., N amplitude tuning circuits) and some phase tuning circuits (e.g., M phase tuning circuits). Since the number of amplitude tuning circuits and the number of phase tuning circuits can be adaptively adjusted, the maximum tuning coverage can be achieved by using the on-chip variable termination circuit 600.

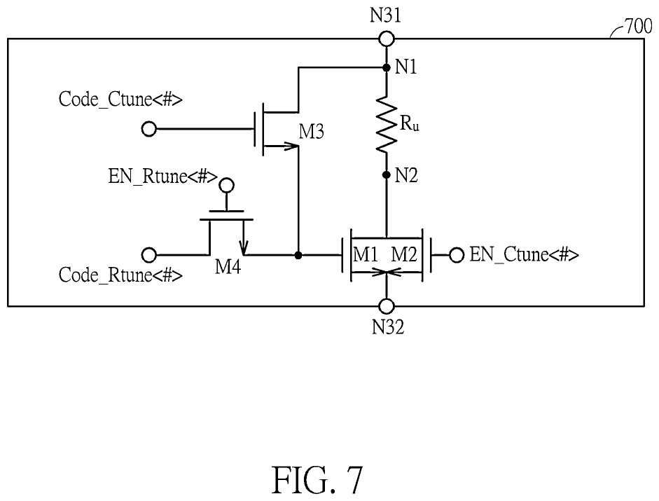

FIG. 7 is a diagram illustrating a reconfigurable tuning circuit according to an embodiment of the present invention. The reconfigurable tuning circuit 700 may be any of the reconfigurable tuning circuits 602_1-602_K and 604_1-604_K shown in FIG. 6. As shown in FIG. 7, the reconfigurable tuning circuit 700 includes a unit resistor Rᵤ and a plurality of MOS transistors M1, M2, M3, M4. The unit resistor Rᵤ has a first end N1 and a second end N2, where the first end N1 is coupled to a first node N31 of the reconfigurable tuning circuit 700.

The MOS transistor M1 has a first connection terminal (e.g., drain terminal), a second connection terminal (e.g., source terminal), and a control terminal (e.g., gate terminal), where the first connection terminal of the MOS transistor M1 is coupled to the second end N2 of the unit resistor Rᵤ, and the second connection terminal of the MOS transistor M1 is coupled to a second node N32 of the reconfigurable tuning circuit 700.

The MOS transistor M2 has a first connection terminal (e.g., drain terminal), a second connection terminal (e.g., source terminal), and a control terminal (e.g., gate terminal), wherein the control terminal of the MOS transistor M2 is configured to receive a phase-tuning configuration enabling signal EN_Ctune<#>, the first connection terminal of the MOS transistor M2 is coupled to the second end N2 of the unit resistor Rᵤ, and the second connection terminal of the MOS transistor M2 is coupled to the second node N32 of the reconfigurable tuning circuit 700. In this embodiment, the MOS transistor M1 may act as a MOS capacitor or a MOS switch, depending on an ON/OFF state of the MOS transistor M2 that is controlled by the phase-tuning configuration enabling signal EN_Ctune<#>.

The MOS transistor M3 has a first connection terminal (e.g., drain terminal), a second connection terminal (e.g., source terminal), and a control terminal (e.g., gate terminal), where the control terminal of the MOS transistor M3 is configured to receive a phase-tuning control signal Code_Ctune<#>, the first connection terminal of the MOS transistor M3 is coupled to the first end N1 of the unit resistor Rᵤ, and the second connection terminal of the MOS transistor M3 is coupled to the control terminal of the MOS transistor M1.

The MOS transistor M4 has a first connection terminal (e.g., drain terminal), a second connection t terminal (e.g., source terminal), and a control terminal (e.g., gate terminal), where the control terminal of the MOS transistor M4 is configured to receive an amplitude-tuning configuration enabling signal EN_Rtune<#>, the first connection terminal of the MOS transistor M4 is configured to receive an amplitude-tuning control signal Code_Rtune<#>, and the second connection terminal of the MOS transistor M4 is coupled to the control terminal of the MOS transistor M1.

The first node N31 of the reconfigurable tuning circuit 700 is coupled to one of the positive signal node VP and the negative signal node VN of the differential signal port (which may be a differential signal output port of a DAC or a differential signal input port of an ADC). And the second node N32 of the reconfigurable tuning circuit 700 is coupled to the voltage node VCM (which may be coupled to a fixed reference voltage AVSS).

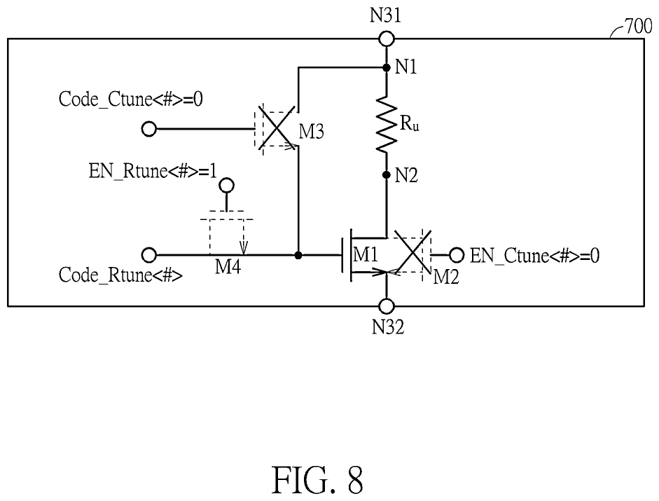

FIG. 8 is a diagram illustrating the reconfigurable tuning circuit 700 that is configured (or reconfigured) as an amplitude tuning circuit. When the reconfigurable tuning circuit 700 is configured (or reconfigured) to act as the amplitude tuning circuit, the amplitude-tuning configuration enabling signal EN_Rtune<#> is set by a logic-high level “1”, the phase-tuning configuration enabling signal EN_Ctune<#> is set by a logic-low level “0”, and the phase-tuning control signal Code_Ctune<#> is set by a logic-low level “0”. Hence, the MOS transistor M2 is turned off, the MOS transistor M3 is turned off, and the MOS transistor M4 is turned on. When the amplitude-tuning control signal Code_Rtune<#> has a logic-high level “1”, the MOS transistor M1 (which acts as a MOS switch) is turned on to enable the unit resistor Rᵤ to make contribution to the amplitude imbalance compensation. When the amplitude-tuning control signal Code_Rtune<#> has a logic-low level “0”, the MOS transistor M1 (which acts as a MOS switch) is turned off to block the unit resistor Rᵤ from making contribution to the amplitude imbalance compensation.

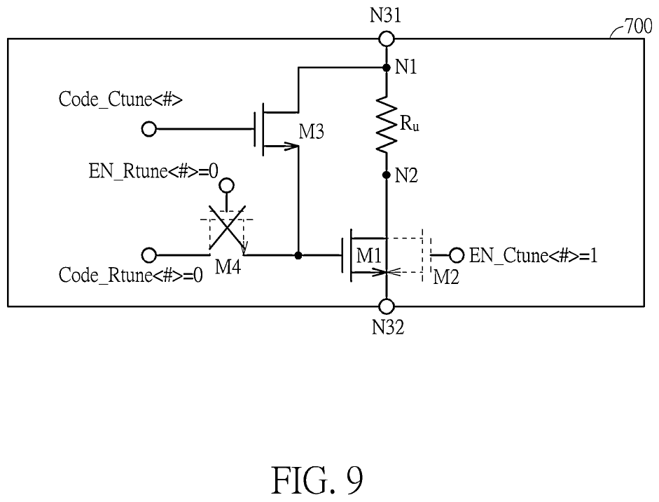

FIG. 9 is a diagram illustrating the reconfigurable tuning circuit 700 that is configured (or reconfigured) as a phase tuning circuit. When the reconfigurable tuning circuit 700 is configured (or reconfigured) to act as the phase tuning circuit, the amplitude-tuning configuration enabling signal EN_Rtune<#> is set by a logic-low level “0”, the phase-tuning configuration enabling signal EN_Ctune<#> is set by a logic-high level “1”, and the amplitude-tuning control signal Code_Rtune<#> is set by a logic-low level “0”. Hence, the MOS transistor M2 is turned on, and the MOS transistor M4 is turned off. The MOS transistor M1 acts as a MOS capacitor (i.e., unit capacitor Cᵤ) due to the turned-on MOS transistor M2. When the phase-tuning control signal Code_Ctune<#> has a logic-high level “1”, the MOS transistor M3 (which acts as a MOS switch) is turned on to enable the unit capacitor Cᵤ (which is implemented by MOS transistor M1) to make contribution to the phase imbalance compensation. When the phase-tuning control signal Code_Ctune<#> has a logic-low level “0”, the MOS transistor M3 (which acts as a MOS switch) is turned off to block the unit capacitor Cᵤ (which is implemented by MOS transistor M1) from making contribution to the phase imbalance compensation.

It should be noted that, when the reconfigurable tuning circuit 700 is configured (or reconfigured) as a phase tuning circuit, the unit resistor Rᵤ is coupled between the first node N31 and the second node N32 of the reconfigurable tuning circuit 700 due to the turned-on MOS transistor M2. Hence, the unit resistor Rᵤ of the reconfigurable tuning circuit 700 used as a phase tuning circuit makes contribution to the amplitude imbalance compensation regardless of the phase-tuning control signal Code_Ctune<#>. Like the on-chip variable termination circuit 300 with amplitude imbalance compensation resulting from any non-reconfigurable phase tuning circuit, the on-chip variable termination circuit 600 has amplitude imbalance compensation resulting from any reconfigurable tuning circuit 700 that is configured (or reconfigured) as a phase tuning circuit. Even though all of the reconfigurable tuning circuits 602_1-602_K of the on-chip variable termination circuit 600 are used as phase tuning circuits, the phase tuning circuits 602_1-602_K are still capable of providing a resistive load Rᵤ K for a positive signal of the differential signals. Similarly, even though all of the reconfigurable tuning circuits 604_1-604_K of the on-chip variable termination circuit 600 are used as phase tuning circuits, the phase tuning circuits 604_1-604_K are still capable of providing a resistive load Rᵤ/K for a negative signal of the differential signals.

For example, considering a case where N reconfigurable tuning circuits among K reconfigurable tuning circuits are selected as amplitude tuning circuits and M (M=K−N) reconfigurable tuning circuits among the K reconfigurable tuning circuits are selected as phase tuning circuits, settings of EN_Rtune, EN_Ctune, Code_Rtune, and Code_Ctune are briefly summarized in the following table 1.

TABLE 1

| | EN_Rtune | EN_Ctune | Code_Rtune | Code_Ctune |
|---|---|---|---|---|
| Amplitude | 1 | 0 | 1-to-N | 0 |
| tuning | | | | |
| circuit | | | | |
| Phase | 0 | 1 | 0 | 1-to- (K-N) |
| tuning | | | | |
| circuit | | | | |
| Forbidden | 1 | 1 | X (Don't-care) | X (Don't-care) |
| Forbidden | 0 | 0 | X (Don't-care) | X (Don't-care) |

With proper settings of the amplitude-tuning control signals Code_Rtune<K:1> (e.g., Code_Rtune_p<K:1> or Code_Rtune_n<K:1>), the phase-tuning control signals Code_Ctune<K:1> (e.g., Code_Ctune_p<K:1> or Code_Ctune_n<K:1>), the amplitude-tuning configuration enabling signals EN_Rtune<K:1> (e.g., EN_Rtune_p<K:1> or EN_Rtune_n<K:1>), and the phase-tuning configuration enabling signals EN_Ctune<K:1> (e.g., EN_Ctune_p<K:1> or EN_Ctune_n<K:1>), the capacitance term Cₜₑᵣₘ involved in phase imbalance compensation and the resistance term Rₜₑᵣₘ involved in amplitude imbalance compensation may be expressed using the following formulas.

$${C}_{term} = {\sum }_{i = 1}^{K - N} ( Code\_Ctune < i > \times EN\_Ctune < i > ) \times {C}_{u} \qquad ( 3 )$$

$${R}_{term} = \frac{{R}_{u}}{{\sum }_{i = 1}^{N} ( Code\_Rtune < i > \times EN\_Rtune < i > ) + {\sum }_{i = 1}^{K - N} EN\_Ctune < i >} \qquad ( 4 )$$

In above embodiments shown in FIG. 3 and FIG. 6, the voltage node VCM is configured to receive a common-mode voltage set by a fixed reference voltage AVSS (AVSS=0V). However, these are for illustrative purposes only, and are not meant to be limitations of the present invention. In some embodiments of the present invention, additional phase tuning coverage can be realized by common-mode voltage tuning. Specifically, the capacitance of the unit capacitor Cᵤ (which is implemented by a MOS capacitor) depends on (VP−VCM) or (VN−VCM). Hence, the capacitance of the unit capacitor Cᵤ can be adaptively adjusted by tuning the common-mode voltage at the voltage node VCM.

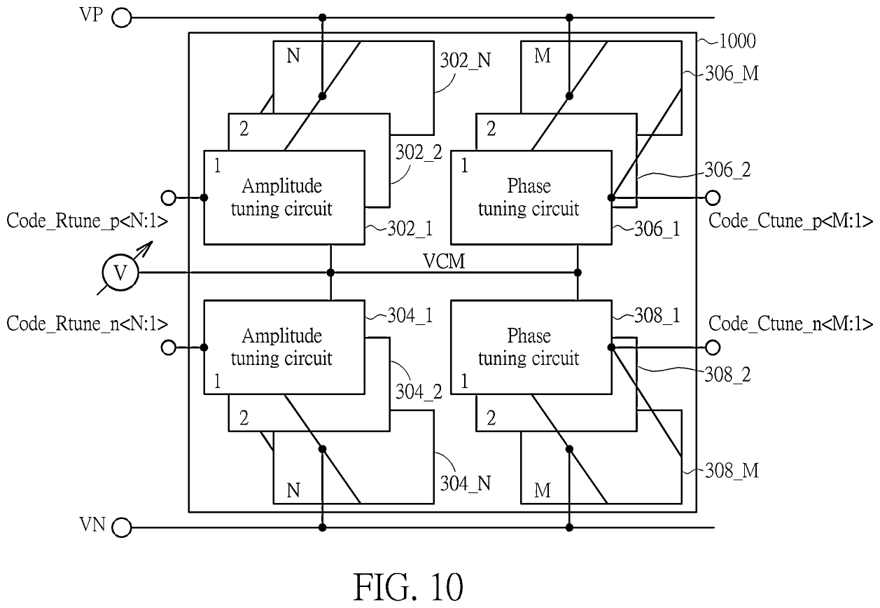

FIG. 10 is a diagram illustrating a third on-chip variable termination circuit according to an embodiment of the present invention. The major difference between the on-chip variable termination circuits 1000 and 300 is that the voltage node VCM of the on-chip variable termination circuit 1000 is configured to receive a tunable common-mode voltage.

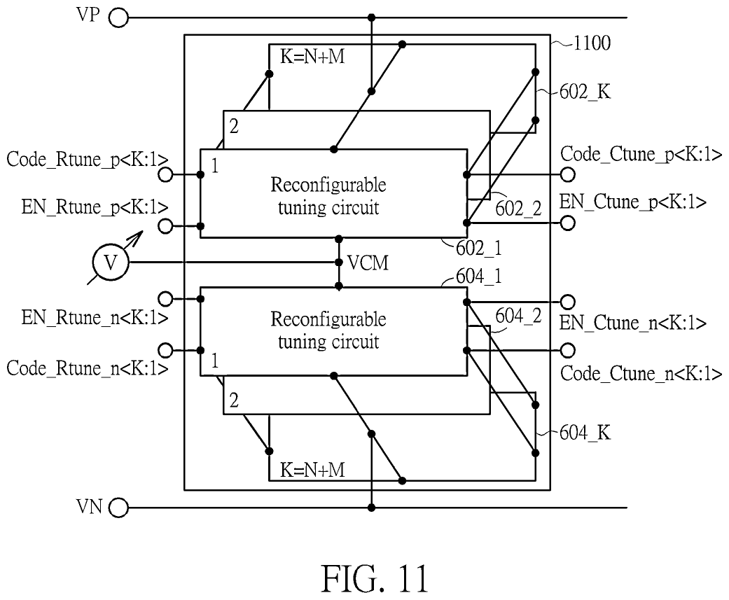

FIG. 11 is a diagram illustrating a fourth on-chip variable termination circuit according to an embodiment of the present invention. The major difference between the on-chip variable termination circuits 1100 and 600 is that the voltage node VCM of the on-chip variable termination circuit 1100 is configured to receive a tunable common-mode voltage.

As shown in FIG. 1 and FIG. 2, the on-chip variable termination circuit 102 may be adaptively adjusted through auto-calibration. Regarding the auto-calibration circuit 104, the detector circuit 106 is configured to sense even-order distortion according to signals obtained from the positive signal node VP and the negative signal node VN of the differential signal port, and the calibration circuit 108 is configured to control all tuning circuits included in the on-chip variable termination circuit 102 according to an output D_OUT of the detector circuit 106. For example, when the on-chip variable termination circuit 102 is implemented by the on-chip variable termination circuit 300/1000, a control output S_CTRL of the calibration circuit 102 may include amplitude-tuning control signals Code_Rtune_p<N:1>, Code_Rtune_n<N:1> and phase-tuning control signals Code_Ctune_p<M:1>, Code_Ctune_n<M:1>. For another example, when the on-chip variable termination circuit 102 is implemented by the on-chip variable termination circuit 600/1100, the control output S_CTRL of the calibration circuit 102 may include amplitude-tuning control signals Code_Rtune_p<K:1>, Code_Rtune_n<K:1>, phase-tuning control signals Code_Ctune_p<K:1>, Code_Ctune_n<K:1>, amplitude-tuning configuration enabling signals EN_Rtune_p<K:1>, EN_Rtune_n<K:1>, and phase-tuning configuration enabling signals EN_Ctune_p<K:1>, EN_Ctune_n<K:1>.

It should be noted that the auto-calibration circuit 104 may be optional. That is, any application using the proposed on-chip variable termination circuit with APIT falls within the scope of the present invention.

In summary, the APIT is capable of tuning on “impedance matching”, “amplitude balance”, and/or “phase balance” in one single circuit; the APIT can be used in the application which converts a single-ended signal into differential signals and/or differential signals into a single-ended signal; the usage of APIT is not limited to the applications containing balun; the APIT is suitable for solving frequency-dependent imbalance; even-order distortion, caused by amplitude/phase imbalance, can be improved by the APIT; and with the APIT, the specification requirement of off-chip components can be relaxed, such as amplitude/phase imbalance of balun or matching of differential components.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A termination circuit comprising:
an on-chip variable termination circuit, comprising:
a plurality of first tuning circuits, each coupled between a positive signal node of a differential signal port and a voltage node, wherein the plurality of first tuning circuits comprise at least one amplitude tuning circuit and at least one phase tuning circuit; and
a plurality of second tuning circuits, each coupled between a negative signal node of the differential signal port and the voltage node, wherein the plurality of second tuning circuits comprise at least one amplitude tuning circuit and at least one phase tuning circuit.

2. The termination circuit of claim 1, wherein each amplitude tuning circuit included in the plurality of first tuning circuits and the plurality of second tuning circuits is a non-reconfigurable amplitude tuning circuit, and each phase tuning circuit included in the plurality of first tuning circuits and the plurality of second tuning circuits is a non-reconfigurable phase tuning circuit.

3. The termination circuit of claim 2, wherein the non-reconfigurable amplitude tuning circuit comprises:
a resistor, having a first end and a second end, wherein the first end is coupled to a first node of the non-reconfigurable amplitude tuning circuit; and
a switch, controlled by an amplitude-tuning control signal and coupled between the second end of the resistor and a second node of the non-reconfigurable amplitude tuning circuit;
wherein one of the first node and the second node of the non-reconfigurable amplitude tuning circuit is coupled to one of the positive signal node and the negative signal node of the differential signal port, and another of the first node and the second node of the non-reconfigurable amplitude tuning circuit is coupled to the voltage node.

4. The termination circuit of claim 2, wherein the non-reconfigurable phase tuning circuit comprises:
a capacitor, having a first end and a second end, wherein the second end is coupled to a second node of the non-reconfigurable phase tuning circuit; and
a switch, controlled by a phase-tuning control signal coupled between a first node of the non-reconfigurable phase tuning circuit and the first end of the capacitor;
wherein the first node of the non-reconfigurable phase tuning circuit is coupled to one of the positive signal node and the negative signal node of the differential signal port, and the second node of the non-reconfigurable phase tuning circuit is coupled to the voltage node.

5. The termination circuit of claim 2, wherein the non-reconfigurable amplitude tuning circuit and the non-reconfigurable phase tuning circuit have same circuit elements but different circuit connections.

6. The termination circuit of claim 1, wherein each of the plurality of first tuning circuits and the plurality of second tuning circuits is a reconfigurable tuning circuit that is configured or reconfigured to act as either an amplitude tuning circuit or a phase tuning circuit.

7. The termination circuit of claim 6, wherein the reconfigurable tuning circuit comprises:
a resistor, having a first end and a second end, wherein the first end is coupled to a first node of the reconfigurable tuning circuit;
a first metal-oxide-semiconductor (MOS) transistor, having a first connection terminal, a second connection terminal, and a control terminal, wherein the first connection terminal of the first MOS transistor is coupled to the second end of the resistor, and the second connection terminal of the first MOS transistor is coupled to a second node of the reconfigurable tuning circuit;
a second MOS transistor, having a first connection terminal, a second connection terminal, and a control terminal, wherein the first connection terminal of the second MOS transistor is coupled to the second end of the resistor, and the second connection terminal of the second MOS transistor is coupled to the second node of the reconfigurable tuning circuit;
a third MOS transistor, having a first connection terminal, a second connection terminal, and a control terminal, wherein the control terminal of the third MOS transistor is configured to receive a phase-tuning control signal, the first connection terminal of the third MOS transistor is coupled to the first end of the resistor, and the second connection terminal of the third MOS transistor is coupled to the control terminal of the first MOS transistor; and
a fourth MOS transistor, having a first connection terminal, a second connection terminal, and a control terminal, wherein the first connection terminal of the fourth MOS transistor is configured to receive an amplitude-tuning control signal, and the second connection terminal of the fourth MOS transistor is coupled to the control terminal of the first MOS transistor;
wherein the first node of the reconfigurable tuning circuit is coupled to one of the positive signal node and the negative signal node of the differential signal port, and the second node of the reconfigurable tuning circuit is coupled to the voltage node.

8. The termination circuit of claim 7, wherein when the reconfigurable tuning circuit is configured or reconfigured to act as the amplitude tuning circuit, the second MOS transistor is turned off, the third MOS transistor is turned off, and the fourth MOS transistor is turned on.

9. The termination circuit of claim 7, wherein when the reconfigurable tuning circuit is configured or reconfigured to act as the phase tuning circuit, the second MOS transistor is turned on, and the fourth MOS transistor is turned off.

10. The termination circuit of claim 1, wherein the voltage node is configured to receive a tunable common-mode voltage.

11. The termination circuit of claim 1, wherein the differential signal port is a differential output port of a processing circuit.

12. The termination circuit of claim 1, wherein the differential signal port is a differential input port of a processing circuit.

13. The termination circuit of claim 1, further comprising:
an auto-calibration circuit, comprising:
a detector circuit, configured to sense even-order distortion according to signals obtained from the positive signal node and the negative signal node of the differential signal port; and
a calibration circuit, configured to control each of the plurality of first tuning circuits and the plurality of second tuning circuits according to an output of the detector circuit.

14. A termination circuit comprising:
an on-chip variable termination circuit, comprising:
a plurality of first tuning circuits, each coupled between a positive signal node of a differential signal port and a voltage node; and
a plurality of second tuning circuits, each coupled between a negative signal node of the differential signal port and the voltage node;
wherein each of the plurality of first tuning circuits and the plurality of second tuning circuits is a reconfigurable tuning circuit that is configured or reconfigured to act as either an amplitude tuning circuit or a phase tuning circuit.

15. The termination circuit of claim 14, wherein the reconfigurable tuning circuit comprises:
a resistor, having a first end and a second end, wherein the first end is coupled to a first node of the reconfigurable tuning circuit;
a first metal-oxide-semiconductor (MOS) transistor, having a first connection terminal, a second connection terminal, and a control terminal, wherein the first connection terminal of the first MOS transistor is coupled to the second end of the resistor, and the second connection terminal of the first MOS transistor is coupled to a second node of the reconfigurable tuning circuit;
a second MOS transistor, having a first connection terminal, a second connection terminal, and a control terminal, wherein the first connection terminal of the second MOS transistor is coupled to the second end of the resistor, and the second connection terminal of the second MOS transistor is coupled to the second node of the reconfigurable tuning circuit;
a third MOS transistor, having a first connection terminal, a second connection terminal, and a control terminal, wherein the control terminal of the third MOS transistor is configured to receive a phase-tuning control signal, the first connection terminal of the third MOS transistor is coupled to the first end of the resistor, and the second connection terminal of the third MOS transistor is coupled to the control terminal of the first MOS transistor; and
a fourth MOS transistor, having a first connection terminal, a second connection terminal, and a control terminal, wherein the first connection terminal of the fourth MOS transistor is configured to receive an amplitude-tuning control signal, and the second connection terminal of the fourth MOS transistor is coupled to the control terminal of the first MOS transistor;
wherein the first node of the reconfigurable tuning circuit is coupled to one of the positive signal node and the negative signal node of the differential signal port, and the second node of the reconfigurable tuning circuit is coupled to the voltage node.

16. The termination circuit of claim 15, wherein when the reconfigurable tuning circuit is configured or reconfigured to act as the amplitude tuning circuit, the second MOS transistor is turned off, the third MOS transistor is turned off, and the fourth MOS transistor is turned on.

17. The termination circuit of claim 15, wherein when the reconfigurable tuning circuit is configured or reconfigured to act as the phase tuning circuit, the second MOS transistor is turned on, and the fourth MOS transistor is turned off.

18. The termination circuit of claim 14, wherein the voltage node is configured to receive a tunable common-mode voltage.

19. The termination circuit of claim 14, further comprising:
an auto-calibration circuit, comprising:
a detector circuit, configured to sense even-order distortion according to signals obtained from the positive signal node and the negative signal node of the differential signal port; and
a calibration circuit, configured to control each of the plurality of first tuning circuits and the plurality of second tuning circuits according to an output of the detector circuit.
